(19) United States
(12) Patent Application Publication
(10) Pub. No.: US 2010/0240161 A1
(43) Pub. Date: Sep. 23, 2010

(54) Method for fabricating nitride semiconductor light-emitting device

(75) Inventors: Takeshi Kamikawa, Osaka (JP); Masataka Ohta, Osaka (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/659,557

(22) Filed: Mar. 12, 2010

(30) Foreign Application Priority Data
Mar. 18, 2009 (JP) 2009-065635 (P)

(51) Int. Cl. H01L 21/20

(52) U.S. Cl. 438/46; 257/E21.09

(57) ABSTRACT

A method for fabricating a nitride semiconductor light-emitting device includes the steps of creating a recessed region in a nitride semiconductor substrate having a nonpolar plane or a semipolar plane, and providing a nitride semiconductor thin film including an n-type nitride semiconductor thin film, an active layer and a p-type nitride semiconductor thin film on the nitride semiconductor substrate. The p-type nitride semiconductor thin film is grown at a growth temperature higher than or equal to 700° C. and lower than 900° C.

This nonprovisional application is based on Japanese Patent Application No. 2009-065635 filed on Mar. 18, 2009 with the Japan Patent Office, the entire contents of which are hereby incorporated by reference.

### BACKGROUND OF THE INVENTION

1. Field of the Invention

The present invention relates to a method for fabricating a nitride semiconductor light-emitting device, and more particularly to a method for fabricating a nitride semiconductor light-emitting device employing a nitride semiconductor substrate having a nonpolar plane or a semipolar plane.

2. Description of the Background Art

Semiconductor laser devices that oscillate in the ultraviolet and visible ranges are being prototyped with nitride semiconductor materials represented by GaN (gallium nitride), AlN (aluminum nitride), InN (indium nitride) and their mixed crystals. Substrates are often embodied by GaN substrates, which are under intense study in many research institutes.

The yield of nitride semiconductor laser devices (e.g., the ratio of good products available from a single wafer) is still poor. For lower manufacturing costs, the yield of nitride semiconductor laser devices needs to be improved.

One reason for such poor yield is the occurrence of cracks. For example, Patent Document 1 discloses that the use of a compound containing GaN as a composition for a nitride semiconductor layer initially provided on a surface of a processed substrate having a hollow recessed region can prevent the occurrence of cracks, and further, a nitride semiconductor layer to be subsequently provided has a highly uniform thickness and a planar surface (e.g., Patent Document 1: Japanese Patent Laying-Open No. 2006-156953, see, e.g., paragraphs [0006] and [0007]).

Poor surface planarity of a thin film and a resultant uneven surface morphology also cause semiconductor light-emitting devices to vary in property, leading to poor yield. To solve these problems, Patent Document 2 discloses a nitride semiconductor light-emitting device with a recessed region created at a position of a substrate or a nitride semiconductor layer including a highly defective region, the recessed region being lowered below a less defective region other than the highly defective region (Patent Document 2: Japanese Patent Laying-Open No. 2004-356454).

As described above, methods for fabricating a nitride semiconductor light-emitting device are known by which a nitride semiconductor thin film including an n-type nitride semiconductor thin film, an active layer, a p-type nitride semiconductor thin film, and the like is provided on a nitride semiconductor substrate with a recessed region created for improving yield in fabricating the nitride semiconductor light-emitting device.

### SUMMARY OF THE INVENTION

FIG. 12 shows a cross section of a nitride semiconductor substrate 1001 having a recessed region A on which nitride semiconductor thin films are provided on the substrate in the order of an n-type nitride semiconductor thin film 1002, an active layer and a p-type nitride semiconductor thin film 1003 (the active layer is interposed between the n- and p-type nitride semiconductor thin films, but not shown in FIG. 12 because of its thinness).

A nitride semiconductor substrate may be embodied by a substrate having a nonpolar plane or a semipolar plane in order to improve the emission luminescence transition probability and the like. Inventors of the present invention have found out that a distinct growth of particularly the p-type nitride semiconductor thin film occurs in the case of creating a recessed region in a nitride semiconductor substrate having a nonpolar plane or a semipolar plane and growing a nitride semiconductor thin film on the surface of the substrate.

As shown in FIG. 12, the distance from a facet surface 1004 of n-type nitride semiconductor thin film 1002 on recessed region A to the surface of p-type nitride semiconductor thin film 1003 is denoted by Lm. The distance from a surface 1005 of n-type nitride semiconductor thin film 1002 on a hill region B to the surface of p-type nitride semiconductor thin film 1003 is denoted by Lp. Hereinafter, Lm may be referred to as “a thickness of the p-type nitride semiconductor thin film in the recessed region” as well, and Lp may be referred to as “a thickness of the p-type nitride semiconductor thin film in the hill region” as well. It has been found out that Lm>Lp holds when providing the p-type nitride semiconductor thin film on the nitride semiconductor substrate having a nonpolar plane or a semipolar plane. It has also been found out that the increase in thickness of the p-type nitride semiconductor thin film is much greater in the horizontal direction (i.e., the direction indicated by an arrow X in FIG. 12) than in the perpendicular direction (i.e., the direction indicated by an arrow Y in FIG. 12), and this horizontal increase in thickness causes recessed region A to be rapidly filled up.

Such a rapid increase in thickness (Lm) of p-type nitride semiconductor thin film 1003 on recessed region A and resultant complete filling of recessed region A created in the nitride semiconductor substrate causes the effects such as preventing the occurrence of cracks to be no longer achieved.

Further, the rapid increase in thickness of p-type nitride semiconductor thin film 1003 on recessed region A and resultant rapid filling up of recessed region A created in the nitride semiconductor substrate causes raw materials consumed in the recessed region to change with time. It has been found out that this change leads to nonuniformity in thickness (Lp) of p-type nitride semiconductor thin film 1003 on hill region B. Nonuniformity in thickness Lp undesirably causes wider variations in in-plane resistance value and nonuniform injection of electric current. A high gain is then unlikely to be achieved, causing a laser oscillation threshold value to increase. The in-plane nonuniformity in thickness Lp also leads to nonuniformity in remaining film thickness of the p-type nitride semiconductor thin film when providing a ridge for optical confinement, so that the state of optical confinement differs within the plane. Such a case is not preferable in that variations in far field pattern occurs, resulting in poor yield and increase in threshold value.

It is therefore very critical to make the thickness (Lp) of the p-type nitride semiconductor thin film on the hill region as uniform as possible within the plane. Studies have revealed that, to make the in-plane distribution of thickness (Lp) of the p-type nitride semiconductor thin film uniform, it is critical to suppress an increase in thickness (Lm) of p-type nitride semiconductor thin film 1003 on recessed region A.

It has also been found out that, when employing an Al-containing p-type nitride semiconductor thin film such as a p-type cladding layer made of AlGaN, a significant increase in thickness Lm leads to nonuniformity in Al composition in the growth direction of the p-type nitride semiconductor thin film in hill region B. Such nonuniformity in Al composition in the p-type nitride semiconductor thin film also needs to be minimized.

Accordingly, the present invention has objects to prevent the recessed region created in the nitride semiconductor substrate having a nonpolar plane or a semipolar plane for improving yield and the like from being filled up during the growth of a nitride semiconductor thin film, and to minimize nonuniformity in Al composition. With these effects, the present invention is aimed at obtaining a nitride semiconductor light-emitting device with high yield.

The present invention is directed to a method for fabricating a nitride semiconductor light-emitting device. The method includes the steps of creating a recessed region in a nitride semiconductor substrate having a nonpolar plane or a semipolar plane, and providing a nitride semiconductor thin film including an n-type nitride semiconductor thin film, an active layer and a p-type nitride semiconductor thin film on the nitride semiconductor substrate. The p-type nitride semiconductor thin film is grown at a growth temperature higher than or equal to 700° C. and lower than 900° C.

According to the present invention, the p-type nitride semiconductor thin film preferably contains Al. Preferably, the n-type nitride semiconductor thin film is grown at a growth temperature higher than or equal to 900° C.

Preferably, the active layer includes a well layer made of InₓGa₁₋ₓN (where x is more than or equal to 0.15).

Preferably, the well layer is grown at a growth temperature higher than or equal to 600° C. and lower than or equal to 830° C. Preferably, the nitride semiconductor substrate having a nonpolar plane or a semipolar plane is a nitride semiconductor substrate having an M plane which is a nonpolar plane.

Preferably, the recessed region is arranged in a stripe shape in a main surface of the nitride semiconductor substrate, and the stripe shape extends in parallel to a c-axis <0001> direction.

Preferably, at the nitride semiconductor substrate having an M plane, an off-angle in a direction parallel to the c-axis <0001> direction ranges from 0.5 to 10 degrees.

Preferably, at the nitride semiconductor substrate having an M plane, an off-angle perpendicular to the c-axis is smaller than the off-angle in the direction parallel to the c-axis.

Preferably, a growth inhibiting film or a growth inhibiting area is provided at a surface of the nitride semiconductor substrate in the recessed region.

In the method for fabricating a nitride semiconductor light-emitting device including the steps of creating a recessed region in a nitride semiconductor substrate having a nonpolar plane or a semipolar plane, and providing an n-type nitride semiconductor thin film, an active layer, a p-type nitride semiconductor thin film, and the like on the substrate, the growth temperature for growing the p-type nitride semiconductor thin film is controlled, so that a rapid lateral growth can be suppressed, and the recessed region can be prevented from being completely filled up with the nitride semiconductor thin film. This achieves the effects of preventing the occurrence of cracks while fabricating the nitride semiconductor light-emitting device, and minimizing nonuniformity in composition in a p-type cladding layer. Further, minimizing nonuniformity in in-plane distribution of thickness of the p-type nitride semiconductor thin film achieves the effect of improving characteristics such as uniform injection of electric current.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are sectional schematic views for explaining a recessed region in a nitride semiconductor substrate.

FIG. 2 is an upper schematic view for explaining the recessed region in the nitride semiconductor substrate.

FIGS. 3A and 3B are sectional schematic views for explaining edge growth of a nitride semiconductor thin film.

FIG. 4 is a sectional schematic view for explaining a stacked structure of a nitride semiconductor light-emitting device according to a first embodiment.

FIG. 5 is an optical microscopic image of a surface morphology when an n-type nitride semiconductor thin film is grown at 800° C.

FIG. 6 is an optical microscopic image of a surface morphology when the n-type nitride semiconductor thin film is grown at 950° C.

FIG. 7 schematically shows the nitride semiconductor light-emitting device according to the first embodiment, where a sectional schematic view is shown at (a) and an upper schematic view is shown at (b).

FIG. 8A is a sectional schematic view of the nitride semiconductor light-emitting device according to the first embodiment, FIG. 8B is an optical microscopic image of a surface of the nitride semiconductor thin film when an indentation created in the surface of the nitride semiconductor thin film on the recessed region has a slope equivalent to an M plane {1-100}, and FIG. 8C is a schematic sectional view of a nitride semiconductor light-emitting device according to a second embodiment.

FIGS. 9A to 9F are sectional schematic views for explaining a method for processing a nitride semiconductor substrate according to the second embodiment.

FIGS. 10A to 10C are sectional schematic views for explaining profiles of a growth inhibiting film according to the second embodiment.

FIGS. 11A and 11B are schematic views for explaining a growth inhibiting area according to the second embodiment, where FIG. 11A shows a state prior to providing a nitride semiconductor thin film, and FIG. 11B shows a state after the nitride semiconductor thin film is provided.

FIG. 12 is a schematic view of a nitride semiconductor thin film provided on a nitride semiconductor substrate having a recessed region by a conventional method.

### DESCRIPTION OF THE PREFERRED EMBODIMENTS

Prior to describing various embodiments according to the present invention below, the meanings of several terms will be clarified first. Note that the present specification mentions indices indicative of crystal planes and directions. In crystallography, a negative index is essentially denoted by its absolute value accompanied with a bar thereon. However, the present specification does not employ such notation, and indicates a negative index with a minus sign “−” added in front of its absolute value.

The term “nitride semiconductor” as used in the present invention represents a nitride semiconductor made of AlₓGa_{y}In_{z}N (0≦x≦1; 0≦y≦1; 0≦z≦1; x+y+z=1). However, approximately 10% or less of a nitrogen element of the nitride semiconductor may be replaced with an As, P or Sb element (only if the hexagonal crystal system of the substrate is maintained). The nitride semiconductor may be doped with Si, O, Cl, S, C, Ge, Zn, Cd, Mg or Be. Among these doping materials, Si, O and Cl are particularly preferable for an n-type nitride semiconductor.

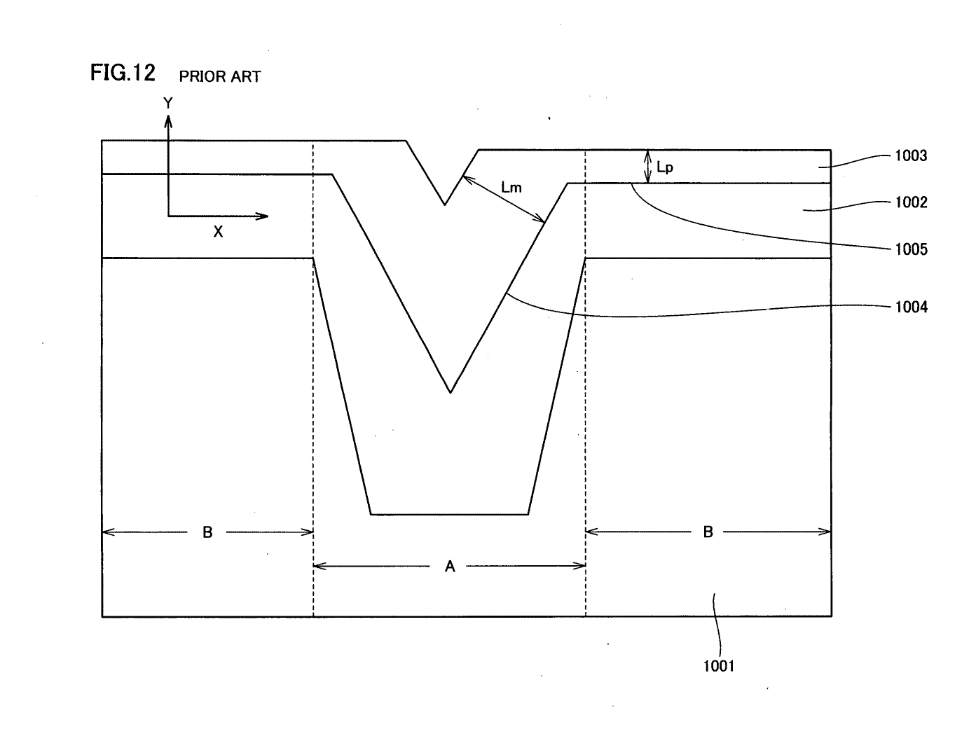

Applying the present invention to the fabrication of a nitride semiconductor light-emitting device employing a nitride semiconductor substrate having a nonpolar plane or a semipolar plane, it has been found out that indentations are created in the surface of p-type nitride semiconductor thin film 1003 on a recessed region 11 shown in FIG. 12. As to the main surface orientation of the nitride semiconductor substrate having a nonpolar plane or a semipolar plane, an A plane {11-20}, an R plane {1-102}, an M plane {1-100}, a plane {1-101}, or a plane {11-22} may be employed. The present invention is highly effective when employing any substrate having a main surface that makes an off angle of 10 degrees or less relative to these crystal surface orientations.

The term “nonpolar plane” as used herein refers to a plane not having a polarity, such as A plane {11-20}, M plane {1-100}, plane {1-101}, or the like. A particularly effective plane is M plane {1-100} or plane {1-101} which is a nonpolar plane. The term “semipolar plane” refers to, for example, plane {11-22}, a plane {10-1-3} or a plane {10-1-1}. A particularly effective plane is plane {11-22}.

The nitride semiconductor substrate having such a nonpolar plane or a semipolar plane can be obtained by, for example, slicing or polishing a bulk crystal of a nitride semiconductor by a conventional method to obtain a plane embodied by a nonpolar plane or a semipolar plane, and processing the plane so as to be a planar surface.

The nitride semiconductor substrate having a nonpolar plane or a semipolar plane preferably has an off-angle of 10 degrees or less. An off-angle in parallel to a recess direction of the recessed region (i.e., the direction perpendicular to the main surface of the nitride semiconductor substrate) is preferably greater than the off-angle in the direction perpendicular to the recess direction. This is preferable because a greater off-angle in parallel to the recess direction than the off-angle in the direction perpendicular to the recess direction can minimize nonuniformity in thickness of the nitride semiconductor thin film which would be likely to vary between regions approximately 30 μm away from the edge of the recessed region. A particularly effective plane is M plane {1-100} or plane {1-101} which is a nonpolar plane.

Recessed Region

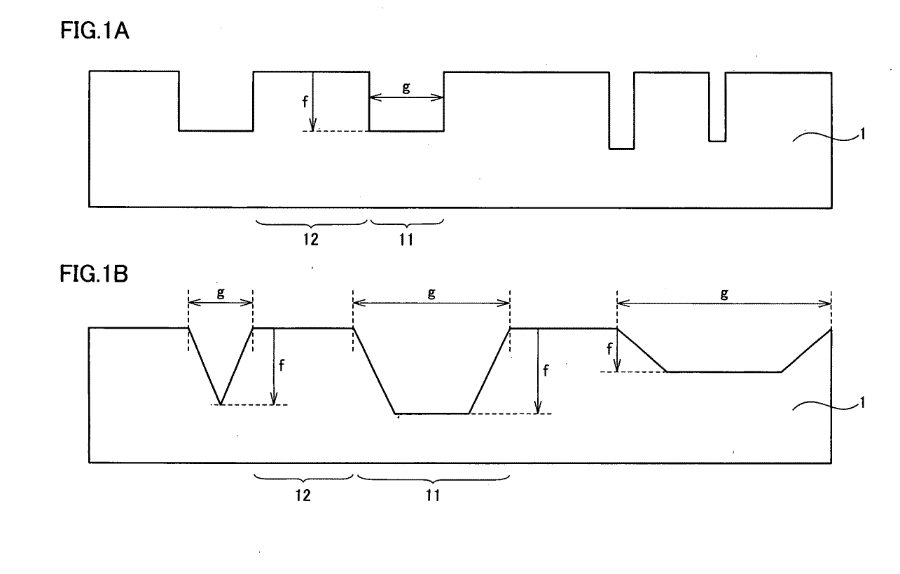

The term “recessed region” as used herein refers to a hollow portion created in the surface of the nitride semiconductor substrate as shown in FIG. 1A, for example. FIG. 1A schematically shows a vertical sectional profile of the substrate after creating the recessed region. The vertical sectional profile of the recessed region does not always need to be rectangular as shown in FIG. 1A, but may have a triangular or trapezoidal profile as shown in FIG. 1B, only if step differences are produced. Recessed region 11 and a hill region 12 shown in FIGS. 1A and 1B are arranged in stripes in a single direction, as viewed from the upper surface. Alternatively, recessed region 11 and hill region 12 may be arranged in a matrix so as to cross each other. Further, recessed regions of different profiles, depths and widths, for example, may be present in a single substrate. Furthermore, the recessed regions may be created at different cycles in a single substrate. It should be noted that, for the sake of clarification and simplification of the drawings of the present invention, the dimensional relationships in terms of length, width, thickness, and depth are changed according to necessity, and actual dimensional relationships may not be shown.

According to the present invention, the recessed region represents a hollow portion created in a stripe shape or the like in the surface of the nitride semiconductor substrate as shown in FIGS. 1A and 1B. The recess depth of the recessed region is the distance from the surface of the processed substrate to the bottom of the recessed region, which is the distance indicated by a character fin FIGS. 1A and 1B, for example. To prevent the occurrence of cracks effectively, the recess depth preferably ranges from 0.1 to 15 μm. Since an extremely shallow depth will cause the recessed region to be rapidly filled up, the depth needs to be greater than or equal to 0.1 μm. A depth greater than or equal to 15 μm will prolong the processing time.

The recessed region in a nitride semiconductor substrate 1 as shown in FIGS. 1A and 1B preferably has an opening width g ranging from 1 to 50 μm. Since it is not preferable to provide a ridge stripe above the recessed region, an opening width greater than or equal to 50 μm will undesirably enlarge an unavailable region within the plane of the nitride semiconductor substrate, resulting in fewer nitride semiconductor light-emitting devices available from a single nitride semiconductor substrate.

It is preferable to create the recessed region in M plane in the stripe shape such that the stripe shape extends in parallel to a c-axis <0001> direction. The off-angle in the direction parallel to the c-axis preferably ranges from 0.5 to 10 degrees, and more preferably from 1.5 to 5 degrees. The off-angle perpendicular to the c-axis is preferably set to be smaller than the off-angle in the direction parallel to the c-axis. This is because, as the off-angle perpendicular to the c-axis is greater than the off-angle in the direction parallel to the c-axis, nonuniform amounts of raw materials may flow into recessed regions created at the right and left sides of a hill region, leading to nonuniformity in distribution in layer thickness. Setting the off-angle in the direction perpendicular to the c-axis to be smaller than the off-angle in the direction parallel to the c-axis achieves effects such as improvement in yield.

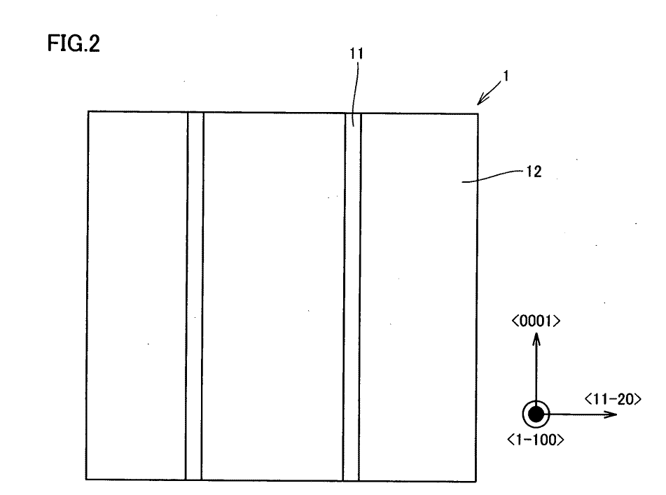

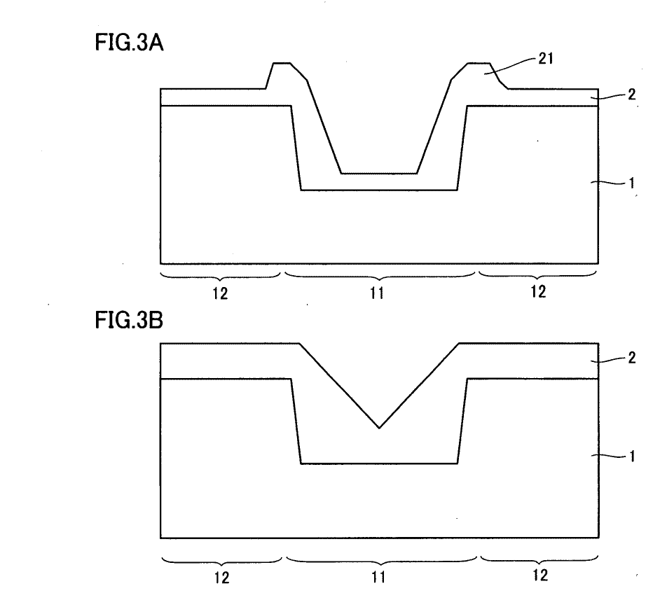

As shown in FIG. 2, it is preferable to create recessed region 11 in the stripe shape in parallel to the c-axis <0001> direction in M plane {1-100} of nitride semiconductor substrate 1. In general, when creating recessed region 11 in nitride semiconductor substrate 1, an edge growth 21 occurs at each side of recessed region 11 where a nitride semiconductor thin film 2 increases in thickness (FIG. 3A). When creating recessed region in the stripe shape in parallel to the c-axis <0001> direction in M plane {1-100} of nitride semiconductor substrate 1, no edge growth occurs, so that nitride semiconductor thin film 2 on hill region 12 has a uniform thickness in a wide area (FIG. 3B). In this case, the p-type nitride semiconductor thin film grows very rapidly in the <11-20> direction (i.e., in the lateral direction toward the center of recessed region 11), so that higher effects can be achieved with the application of the present invention.

In this case, it is preferable to provide a ridge stripe (optical waveguide region) in the hill region in terms of uniformity in layer thickness. A uniform layer thickness in a wide area is highly advantageous in reducing the chip size to increase the number of laser devices available from a single wafer. For reducing the chip size to obtain a greater number of devices, the ridge stripe needs to be disposed in proximity to the recessed region. At this stage, the layer thickness needs to be uniform in proximity to the recessed region in terms of yield.

The Case of Polar Plane

If the p-type nitride semiconductor thin film is grown at a growth temperature lower than 900° C. (Tg<900° C.) on a nitride semiconductor substrate having a C plane which is a polar plane that is not covered by the present invention, a great number of defects (due to threading dislocations or the like) will be produced at the surface of the p-type nitride semiconductor thin film. The defects at the surface are so large that they can be observed through an optical microscope at the magnification of approximately 200× to 800×. In general, defects can only be observed through a scanning electron microscope (SEM) or the like.

This is considered because a low growth temperature suppresses migration of atoms, resulting in degraded crystallinity. A nitride semiconductor is likely to exhibit an n-type conduction, and less likely to exhibit a p-type conduction. When fabricated at a low temperature, the nitride semiconductor no longer exhibits the p-type conduction because of degraded crystallinity. Accordingly, the p-type nitride semiconductor thin film is grown at a high temperature, e.g., approximately 1000° C. on a polar plane. Particularly, the growth temperature of an Al-containing AlGaN nitride semiconductor thin film needs to be higher than that of a GaN nitride semiconductor thin film.

The Case of Nonpolar Plane or Semipolar Plane

It has been found out that, when growing the p-type nitride semiconductor thin film at a growth temperature Tg lower than 900° C. (Tg<900° C.) on a nitride semiconductor substrate having a nonpolar plane or a semipolar plane as in the present invention, the lateral growth of the p-type nitride semiconductor thin film can be effectively suppressed. The p-type nitride semiconductor thin film is more preferably grown at a growth temperature higher than or equal to 600° C. and lower than or equal to 880° C. When growing the p-type nitride semiconductor thin film at a growth temperature lower than 600° C., a great number of pyramidal projections occur at the grown surface. These pyramidal projections lead to nonuniformity in thickness of the p-type nitride semiconductor thin film, causing nonuniform injection of electric current into the active layer. This case is not preferable in that gains may vary within the plane, and the threshold value may increase. At lower growth temperatures, a greater number of pyramidal projections occur. Growing the p-type nitride semiconductor thin film at a growth temperature higher than or equal to 600° C. can prevent the occurrence of pyramidal projections, and minimize nonuniformity in in-plane distribution of thickness Lp of the p-type nitride semiconductor thin film on the hill region.

### First Embodiment

The present embodiment addresses a method for fabricating a nitride semiconductor light-emitting device, including the steps of creating a recessed region in a nitride semiconductor substrate having a nonpolar plane or a semipolar plane, and providing a nitride semiconductor thin film including an n-type nitride semiconductor thin film, an active layer and an Al-containing p-type nitride semiconductor thin film on the nitride semiconductor substrate. The p-type nitride semiconductor thin film is grown at a growth temperature higher than or equal to 700° C. and lower than 900° C. A detailed description will be given below.

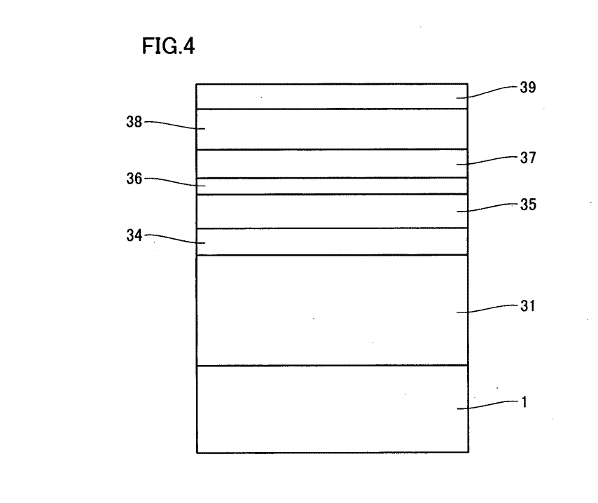

The case of growing the nitride semiconductor thin film directly on the nitride semiconductor substrate will be described with reference to FIGS. 2 and 4. According to the present embodiment, a nitride semiconductor thin film shown in FIG. 4 (31 to 39 in FIG. 4) is grown by MOCVD on the surface of nitride semiconductor substrate 1 with recessed region 11 created in the stripe shape as shown in FIG. 2, to thereby fabricate a nitride semiconductor light-emitting device having indentations in the surface of the semiconductor thin film on the recessed region.

As shown in FIG. 4, according to the present embodiment, a 2.2 μm-thick n-type Al_{0.050}Ga_{0.950}N first cladding layer 31, a 0.1-μm-thick n-type GaN guide layer 34, a 12-nm-thick InGaN/InGaN-2QW active layer 35 (InGaN/InGaN=4 nm/8 nm), a p-type Al_{0.15}Ga_{0.85}N evaporation preventing layer 36 (of 20 nm thickness), a p-type GaN guide layer 37 (of 0.05 um thickness), a p-type Al_{0.050}Ga_{0.950}N cladding layer 38 (of 0.5 μm thickness), and p-type GaN contact layer 39 (of 0.1 μm thickness) are stacked on nitride semiconductor substrate 1 in the cited order.

Herein, the nitride semiconductor substrate is embodied by a 0.1-μm-thick n-type GaN substrate having M plane {1-100} with a recessed region created in the stripe shape at a width of 5 μm, a depth of 3 μm and a cycle of 400 μm in the <0001> direction by vapor phase etching such as RIE (Reactive Ion Etching) or ICP (Ion Coupled Plasma) etching.

According to the present invention, the nitride semiconductor substrate may be etched by vapor phase etching or etching with a liquid-phase etchant. The recessed region may be created after once growing nitride semiconductor thin films such as those made of GaN, InGaN, AlGaN, InAlGaN, and InAlN on the GaN substrate. That is, the present invention is also applicable in the case of first growing a nitride semiconductor thin film, creating the recessed region, and then growing the nitride semiconductor thin film.

Growth of P-Type Nitride Semiconductor Thin Film

Herein, the growth temperature of each layer is a critical issue for preventing a groove serving as the recessed region from being filled up with the growth of the nitride semiconductor thin film, and further for minimizing nonuniformity in composition in p-type AlGaN cladding layer 38. Since the lateral growth of the p-type nitride semiconductor thin film is particularly very significant on the nitride semiconductor substrate having a nonpolar plane, the thickest cladding layer (p-type AlGaN cladding layer 38) among p-type nitride semiconductor thin films needs to be grown at a growth temperature lower than 900° C.

P-type Al_{0.050}Ga_{0.950}N cladding layer 38 (of 0.5 μm thickness) employed in the present embodiment may be replaced with a mixed crystal of InₛAlₜGaᵤN (s+t+u=1, 0≦s<1, 0<t≦1, 0<u<1). This composition may be determined according to necessity to attain a refractive index necessary for optical confinement. When growing this mixed-crystal p-type cladding layer at a growth temperature higher than or equal to 900° C., it has been found out that the p-type AlGaN cladding layer in the hill region has a nonuniform Al composition in the growth direction.

This is because the recessed region is more rapidly filled up with the significant lateral growth of the p-type nitride semiconductor thin film as the film growth progresses, causing the groove created in the recessed region to be abruptly reduced in volume. When an unfilled portion of the groove has a large volume, Ga atoms having a longer diffusion length than Al flow into the groove, causing a shortage of Ga atoms in the hill region. At this stage, the hill region has a high Al composition. It is considered that, as the groove is filled further, a fewer amount of Ga atoms flows into the groove, so that the cladding layer in the hill region has a lower value of Al composition.

In contrast, growing the p-type cladding layer at a growth temperature lower than 900° C. reduces the diffusion lengths of Ga and Al, causing a fewer amount of Ga atoms to flow into the groove above the recessed region, so that the groove above the recessed region is less likely to be filled up. This can minimize nonuniformity in thickness distribution of the p-type nitride semiconductor thin film. Further, lowering the growth temperature of the p-type cladding layer can also minimize nonuniformity in composition of the p-type cladding layer on the hill region in the growth direction.

When the growth temperature is higher than or equal to 900° C., the Al composition varies within a range of 3% Al composition≦8% in the case of setting the Al composition ratio (i.e., the weight ratio of the p-type cladding layer with respect to all compositions) at 5%. When growth temperature Tg is lower than 900° C. (Tg<900° C.), 4%≦Al composition≦6.5% holds in the case of setting the Al composition ratio at 5%, and when growth temperature Tg is lower than or equal to 880° C., 4.5%≦Al composition≦5.5% holds. This reveals that growing the p-type nitride semiconductor thin film (p-type cladding layer) at a growth temperature lower than 900° C. can remarkably minimize nonuniformity in Al composition.

The reason why growing the p-type nitride semiconductor thin film (p-type cladding layer) at a growth temperature lower than 900° C. can remarkably minimize nonuniformity in Al composition is considered because the difference between the diffusion lengths of Ga atoms and Al atoms decreases within such temperature range, leading to a smaller difference between the amounts of Al atoms and Ga atoms flowing into the groove. In other words, growing the Al-containing p-type nitride semiconductor thin film on the nitride semiconductor substrate having a nonpolar plane or a semipolar plane at a growth temperature lower than 900° C. can minimize nonuniformity in Al composition.

Such characteristic is a distinctive characteristic remarkably exhibited when providing the nitride semiconductor thin film on a nonpolar plane or a semipolar plane of the nitride semiconductor substrate. Particularly on the nonpolar plane, when growing the p-type nitride semiconductor thin film at lower growth temperatures, the effect of minimizing nonuniformity in composition is greater. This is also considered because the nonpolar plane, lacking a polarity, does not clearly exhibit sites at which Ga atoms and N atoms should be located, so that the diffusion lengths are longer than in a polar plane.

It should be noted that, similarly to p-type cladding layer 38, p-type Al_{0.15}Ga_{0.85}N evaporation preventing layer 36 (of 20 nm thickness) is also preferably grown at a growth temperature lower than 900° C., but considering its small thickness, may be grown at a growth temperature higher than or equal to 900° C. so as to minimize nonuniformity in degree of filling of the groove.

Since p-type GaN contact layer 39 (of 0.1 μm thickness) is not made of a mixed crystal, nonuniformity in composition due to the difference in growth temperatures do not occur. P-type GaN contact layer 39 may therefore be grown at a growth temperature higher than or equal to 900° C., but is preferably grown at a growth temperature lower than 900° C. such that the groove is less likely to be filled up.

Although the structure described in the present embodiment does not include a p-type optical guide layer, such a p-type optical guide layer may be provided without problems. When providing such a p-type optical guide layer, an InₛAlₜGaᵤN layer (s+t+u=1, 0≦s<1, 0<t≦1, 0<u<1) may be provided in a thickness of 0.05 to 0.5 μm on the evaporation preventing layer. The p-type optical guide layer, containing an Al composition, is preferably grown at a growth temperature lower than 900° C. for the purpose of minimizing nonuniformity in composition.

Further, it has been found out that, employing a nitride semiconductor substrate having a nonpolar plane or a semipolar plane, doping with Mg as an impurity allows the nitride semiconductor thin film to exhibit the p-type conduction even when the growth temperature of the nitride semiconductor thin film is lower than 900° C. When a nitride semiconductor thin film is provided on the C plane which is a polar plane, the nitride semiconductor thin film significantly increases in resistance and is difficult to use as a device. When a nitride semiconductor thin film is provided on a nitride semiconductor substrate having a nonpolar plane or a semipolar plane, the nitride semiconductor thin film can exhibit the p-type conduction. However, it has been found out that the p-type nitride semiconductor thin film increases in resistance when the substrate has a temperature lower than 700° C. Accordingly, the p-type cladding layer is preferably grown at a growth temperature higher than or equal to 700° C. and lower than 900° C., and more preferably higher than or equal to 700° C. and lower than or equal to 880° C.

When an InₓGa₁₋ₓN nitride semiconductor thin film (0<x<1) included in a well layer of the active layer has an In composition of 0.15≦x, the segregation of In and the like cause nonuniformity in In composition within the plane. Accordingly, the p-type nitride semiconductor thin film is preferably grown at a lower growth temperature. When the InₓGa₁₋ₓN nitride semiconductor thin film has the In composition of 0.15≦x, it is more preferable to grow the p-type nitride semiconductor thin film at a growth temperature lower than 900° C. in terms of avoiding thermal damage to the active layer. Further, for avoiding thermal damage to the active layer, the difference between the growth temperatures of the well layer of the active layer and the p-type nitride semiconductor thin film is more preferably smaller than 200° C., and still more preferably smaller than or equal to 150° C.

Growth of N-Type Nitride Semiconductor Thin Film

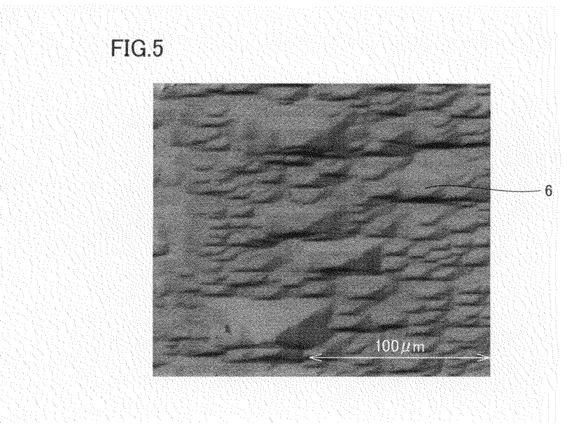

N-type Al_{0.050}Ga_{0.950}N first cladding layer 31 (of 2.2 μm thickness) and n-type GaN guide layer 34 (of 0.1 μm thickness) are grown sequentially on n-type GaN substrate 1 (of 0.1 μm thickness) having an M plane. The above-noted n-type nitride semiconductor thin film is preferably grown at a growth temperature higher than or equal to 900° C. As described above, when employing the nitride semiconductor substrate having a nonpolar plane and growing the n-type nitride semiconductor thin film at a growth temperature lower than 900° C., pyramidal projections occur. This phenomenon occurs significantly at lower growth temperatures, and a greater number of pyramidal projections occur. FIG. 5 is an optical microscopic image of a surface morphology when the n-type nitride semiconductor thin film is grown at 800° C. on the surface of the nitride semiconductor substrate having a nonpolar plane. As can be seen, a great number of pyramidal projections 6 occur. It has been found out that pyramidal projections 6 occur at low growth temperatures, regardless of the presence or absence of the recessed region.

Studies on how to prevent the occurrence of these pyramidal projections have revealed that growing the n-type nitride semiconductor thin film at a high temperature higher than or equal to 900° C. to planarize the n-type nitride semiconductor thin film, and providing the active layer and the p-type nitride semiconductor thin film on the planarized n-type nitride semiconductor thin film can prevent the occurrence of pyramidal projections at the active layer and the p-type nitride semiconductor thin film even when the active layer and the p-type nitride semiconductor thin film are grown at low temperatures.

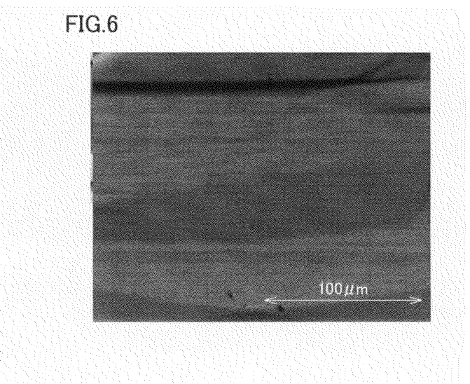

FIG. 6 is an optical microscopic image of a surface morphology when the n-type nitride semiconductor thin film is grown at 950° C. The n-type nitride semiconductor thin film is more preferably grown at a growth temperature higher than or equal to 1000° C. However, even when the n-type nitride semiconductor thin film is grown at a growth temperature higher than or equal to 900° C., pyramidal projections occur as the thickness of the p-type nitride semiconductor thin film (the total thickness of layers doped with Mg: in the present embodiment, the total thickness of evaporation preventing layer 36 and p-type GaN guide layer 37 provided thereon) increases. Accordingly, the thickness of the p-type nitride semiconductor thin film is preferably smaller than 1.5 μm, and more preferably smaller than or equal to 1 μm.

The n-type nitride semiconductor thin film includes a plurality of layers, which are preferably grown at suitable growth temperatures, respectively. Particularly, since the n-type cladding layer contains Al, the n-type cladding layer is preferably grown at a high growth temperature. The effects of the present invention can be achieved when growing at least the n-type cladding layer at a growth temperature higher than or equal to 900° C. The n-type GaN guide layer, for example, is as thin as approximately 0.1 μm, and hence, in this case, the n-type guide layer alone may be grown at 800° C. without problems.

Growing the n-type nitride semiconductor thin film at a growth temperature lower than 900° C. can further prevent the recessed region from being filled up with the nitride semiconductor thin film. However, to prevent the occurrence of pyramidal projections and also to effectively leave indentations in the recessed region (and further, to minimize nonuniformity in composition in the p-type cladding layer), the n-type nitride semiconductor thin film needs to be grown at a growth temperature higher than or equal to 900° C., and the p-type nitride semiconductor thin film needs to be grown at a growth temperature lower than 900° C.

To effectively leave indentations created in the nitride semiconductor thin film when grown on the nitride semiconductor substrate having the recessed region, the n-type nitride semiconductor thin film is also preferably grown at a growth temperature lower than 900° C. However, since the p-type nitride semiconductor thin film exhibits a lateral growth stronger than that of the n-type nitride semiconductor thin film, the p-type nitride semiconductor thin film is preferably grown at a temperature lower than the n-type nitride semiconductor thin film. In addition, since the p-type nitride semiconductor thin film is generally thinner than the n-type nitride semiconductor thin film, the p-type nitride semiconductor thin film is preferably grown at a still lower temperature.

Growth of Active Layer

The well layer of the active layer is preferably grown at a growth temperature higher than or equal to 600° C. and lower than or equal to 830° C. The well layer is made of In₁₋ₓ GaₓN (0<x<1), where the In composition x is determined in accordance with an optical wavelength demanded of devices. When the In composition x is greater than or equal to 0.15, the growth temperature is preferably higher than or equal to 600° C. and lower than or equal to 770° C. At higher temperatures exceeding this range, thermal damage will cause blackening. The growth temperature is more preferably higher than or equal to 630° C. and lower than or equal to 740° C. Growth temperatures lower than 600° C. will undesirably shorten the diffusion lengths of atoms, resulting in degraded crystallinity.

The nitride semiconductor wafer fabricated by the above-described method is processed into a semiconductor laser. The semiconductor laser is then subjected to processing, which is well known and detailed description thereof will not be given herein. To summarize, a ridge structure serving as a current-narrowing structure is fabricated, followed by production of a p-electrode (e.g., Pd/Pt/Au=15 nm/15 nm/200 nm on p-type nitride semiconductor), grinding of the substrate, and then production of an n-electrode (Hf/Al/Mo/Pt/Au=5 nm/150 nm/36 nm/18 nm/200 nm) on a back surface of the substrate (where no nitride semiconductor thin film is grown). This wafer is divided into bars. The division is made such that a semiconductor laser device has a cavity length ranging from 300 to 1800 μm. In the present embodiment, the wafer is divided into bars such that the cavity length is 1200 μm. Then, each bar is divided into respective semiconductor laser devices.

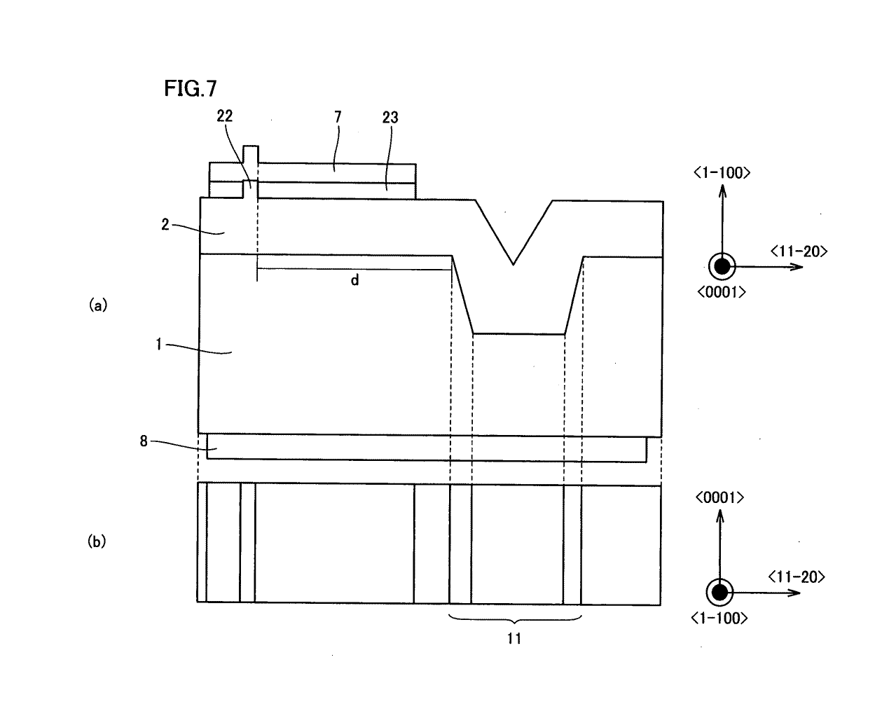

A nitride semiconductor light-emitting device (LD device) thus obtained will be described below with reference to FIG. 7 schematically showing a sectional view of the nitride semiconductor light-emitting device.

FIG. 7 shows, at (a), a sectional schematic view of semiconductor laser device 1 according to the first embodiment of the present invention, as viewed from a light outgoing direction. FIG. 7 also shows, at (b), a schematic view (upper schematic view) of semiconductor laser device 1, as viewed from the upper surface. In FIG. 7, nitride semiconductor substrate (n-type GaN substrate) 1 having M plane {1-100} at (a) corresponds to nitride semiconductor substrate 1 shown in FIG. 4. The GaN substrate has recessed region 11 created in the stripe shape.

Nitride semiconductor thin film (epitaxially grown layer) 2 having the same structure as that of layers 31 to 39 shown in FIG. 4 is provided on nitride semiconductor substrate 1 having recessed region 11. Nitride semiconductor thin film 2 is provided with a laser stripe 22 serving as a laser optical waveguide structure. Laser stripe 22 is arranged in a direction substantially parallel to the stripe shape of the recessed region. Arranging laser stripe 22 in the direction substantially parallel to the stripe shape of the recessed region is preferable in that nonuniformity in film thickness directly under laser stripe 22 is further minimized.

Further provided on nitride semiconductor thin film 2 is an insulation film 23 made of SiO₂ (or an oxide insulation film made of TiO₂ or ZrO₂, for example, may be employed) for current-narrowing purpose, and provided on the upper surface of insulation film 23 is a p-electrode 7. Provided on the lower surface of nitride semiconductor substrate 1 is an n-electrode 8. The nitride semiconductor light-emitting device (nitride semiconductor laser) fabricated by the method described in the present embodiment has no cracks in the nitride semiconductor wafer, so that the occurrence of cracks can be totally prevented. Further, since nonuniformity in Al composition in the p-type nitride semiconductor thin film is minimized, the voltage is reduced by approximately 0.5V on average as compared to a conventional device to which the present invention is not applied. Moreover, variations in far field pattern (FFP) are reduced, so that the yield is improved approximately from 50% to 75%.

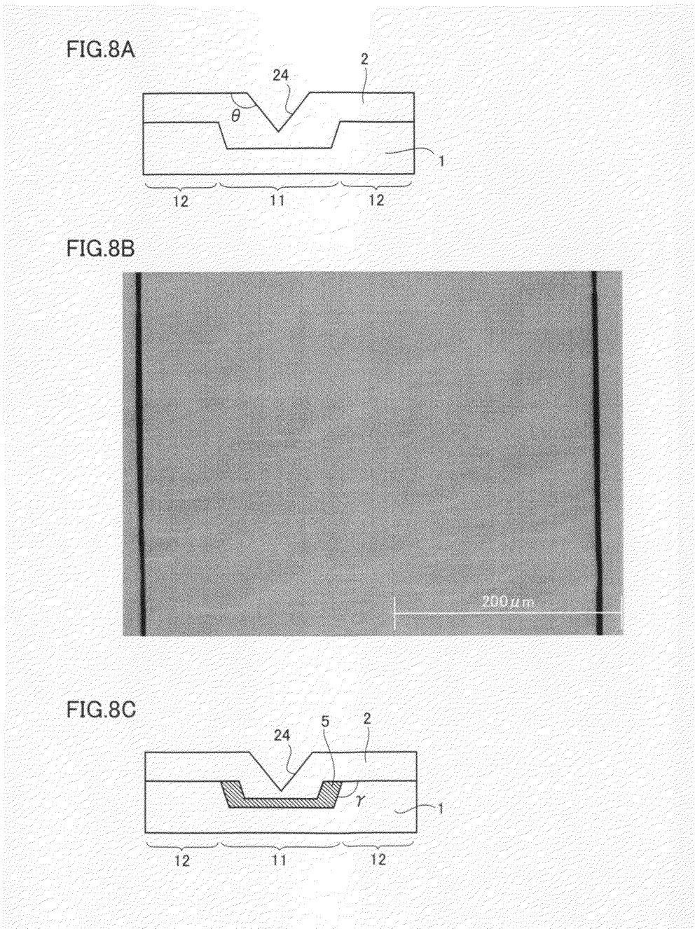

Furthermore, as shown in FIG. 8A, it has been found out that, when a slope 24 of an indentation created in the surface of nitride semiconductor thin film 2 on recessed region 11 of nitride semiconductor substrate 1 is equivalent to M plane {1-100}, the surface morphology is improved. FIG. 8B is an optical microscopic image of the surface of nitride semiconductor thin film 2 when the indentation created in nitride semiconductor thin film 2 has slope 24 equivalent to M plane. Representing the angle between the surface of nitride semiconductor thin film 2 on hill region 12 and slope 24 of the indentation by θ as shown in FIG. 8A, the slope of the indentation becomes equivalent to M plane {1-100} when A reaches approximately 120 degrees. According to the present embodiment, the surface of the nitride semiconductor thin film on the recessed region can efficiently be equivalent to M plane {1-100} that makes an angle of approximately 120 degrees with the surface of the nitride semiconductor thin film above the hill region. Accordingly, the surface morphology of nitride semiconductor thin film 2 can further be improved. This is considered because the above-mentioned two growth surfaces have the same growth rate since they are equivalent, which minimizes nonuniformity in layer thickness. This is particularly effective on an M plane substrate. That is, the surface morphology is improved by making the slope of the indentation created in the surface of the nitride semiconductor thin film on the recessed region equivalent to the crystal plane of the nitride semiconductor thin film on a region other than the recessed region.

### Second Embodiment

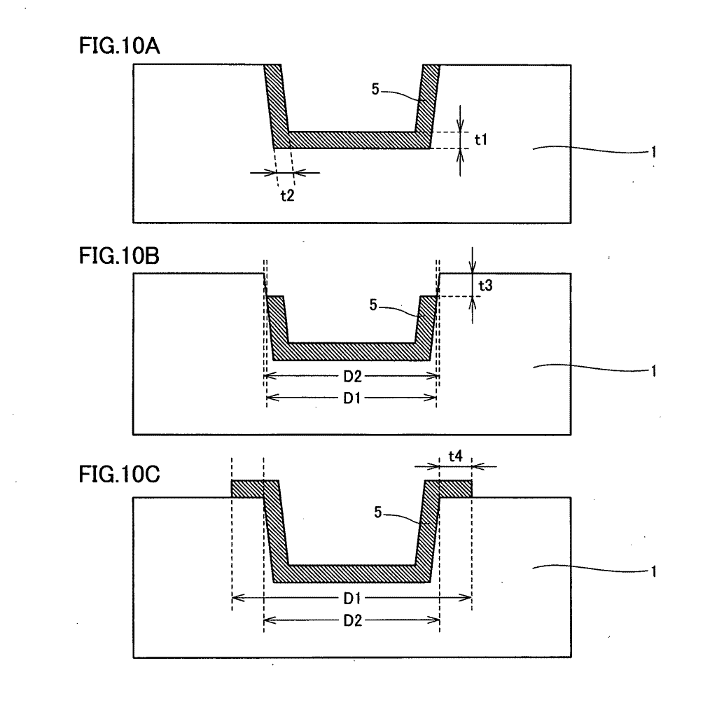

The present embodiment addresses a method for fabricating a nitride semiconductor light-emitting device similar to that of the first embodiment except that a growth inhibiting film 5 is provided in a recessed region of a nitride semiconductor substrate as shown in FIGS. 10A to 10C which will be described later, and a nitride semiconductor thin film is then provided on the nitride semiconductor substrate. FIG. 8C shows the nitride semiconductor light-emitting device obtained by the present embodiment. While the effects of the present invention can be achieved by the first embodiment, providing the growth inhibiting film as in the present embodiment can further slow down the growth rate of the nitride semiconductor thin film (particularly, the p-type nitride semiconductor thin film) on the recessed region.

Provision of Growth Inhibiting Film

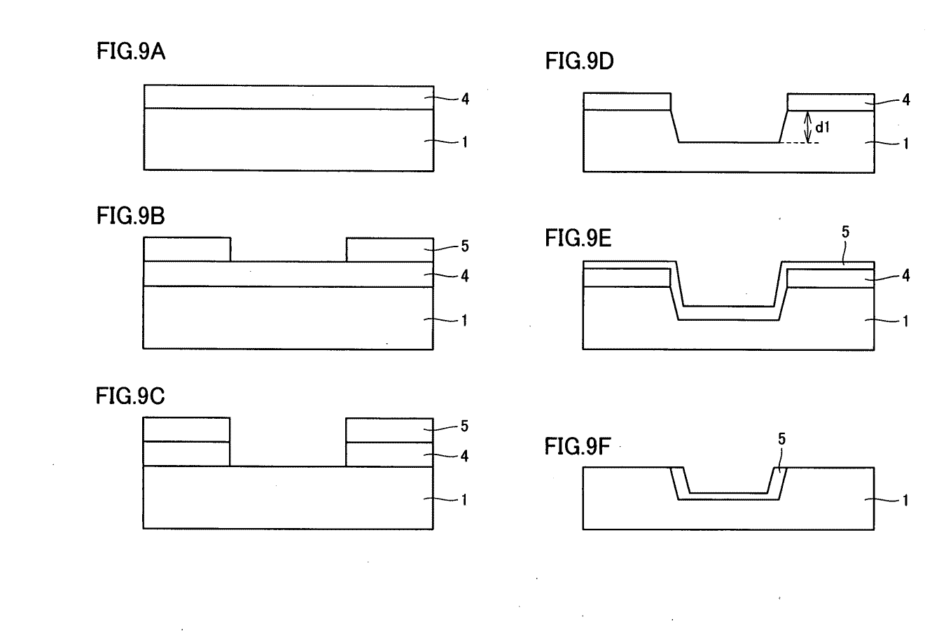

An example of a method for providing the growth inhibiting film in the recessed region will now be described in detail with reference to FIGS. 9A to 9F. As shown in FIG. 9A, a sputtering process is applied (or another process such as Electron Beam deposition or a plasma CVD process may be employed) to cause SiO₂ or the like to adhere to the whole surface of nitride semiconductor substrate (GaN substrate) 1, thereby obtaining a 1-μm-thick SiO₂ layer 4. Then, as shown in FIG. 9B, a typical photolithography process is applied to a resist 5 to create a window in the stripe shape at a width of 5 μm and a cycle of 400 μm in the <0001> direction. The cycle herein is determined depending on the width of a semiconductor laser device in a direction perpendicular to the direction of the stripe shape. In order for the device to have a width of 200 μm, the cycle should be 200 μm. In FIG. 9C, an RIE (Reactive Ion Etching) process or the like is applied to etch SiO₂ layer 4 using resist 5 as a mask. After etching, resist 5 is removed by organic cleaning (with acetone, ethanol or the like). The next step may be carried out without removing resist 5. As shown in FIG. 9D, an ICP (Inductively Coupled Plasma) process or RIE (Reactive Ion Etching) process is applied to etch nitride semiconductor substrate 1 using SiO₂ layer 4 as a mask. An etching depth of nitride semiconductor substrate 1 is 5 μm (the etching depth is indicated by a depth d1 in FIG. 9D). As shown in FIG. 9E, a sputtering process is applied (or another process such as Electron Beam deposition, a plasma CVD process, an ECR (Electron cyclotron resonance) process or a plasma sputtering process may be employed) to provide a 0.2-μm-thick growth inhibiting film 5 made of aluminum nitride (AlN).

Then, as shown in FIG. 9F, SiO₂ layer 4 is removed by an etchant such as HF, and a lift-off process is applied to leave growth inhibiting film 5 on the side and bottom faces of the groove. The above-described steps are carried out to complete processing of nitride semiconductor substrate 1 prior to growing the nitride semiconductor thin film. The substrate thus obtained is shown in FIG. 10A.

FIGS. 10B and 10C show that growth inhibiting film 5 provided in recessed region 11 of nitride semiconductor substrate 1 may have different profiles from that in FIG. 10A. As shown in FIG. 10B, growth inhibiting film 5 has a width D1 narrower than a width D2 of a groove opening of nitride semiconductor substrate 1. In contrast, in FIG. 10C, growth inhibiting film 5 has width D1 wider than width D2 of the groove opening of nitride semiconductor substrate 1, and growth inhibiting film 5 is also provided on a region other than the recessed region of nitride semiconductor substrate 1. In FIG. 10A, the width of the growth inhibiting film is equal to the width of the groove opening.

An example of the methods shown in FIGS. 10B and 10C will be described. SiO₂ layer 4 is provided on nitride semiconductor substrate 1 similarly to the above-described steps shown in FIGS. 9A to 9D. SiO₂ layer 4 is then removed by an etchant such as HF to obtain nitride semiconductor substrate 1 having the recessed region (in this state, growth inhibiting film 5 has not yet been provided). A resist is then applied to the whole surface of nitride semiconductor substrate 1, and in the case of FIG. 10B, the resist is removed by photolithography in a region smaller than the opening of the recessed region in nitride semiconductor substrate 1. Growth inhibiting film 5 is then provided by sputtering, EB deposition, plasma CVD, or the like. A lift-off process is then applied to leave growth inhibiting film 5 in a region smaller than the opening of the recessed region. In the case of FIG. 10C, a resist is applied to the whole surface of the substrate, and removed by photolithography in a region larger than the opening of the recessed region in nitride semiconductor substrate 1. Growth inhibiting film 5 is similarly provided, and left in the region larger than the opening of the recessed region. A distance t4 preferably falls within a range of 0 μm<t4≦30 μm.

Inclination of Side Face of Recessed Region

In the present embodiment, the growth inhibiting film is preferably provided using an apparatus such as an ECR sputtering apparatus, however, EB deposition or the like may alternatively be employed. When employing EB deposition or the like, the growth inhibiting film may be extremely thin at the side face of the recessed region so as not to constitute a film, or no growth inhibiting film may be provided. Such a phenomenon can be avoided by increasing an inclination γ of a side face 111 of recessed region 11 shown in FIG. 8C to be greater than 90 degrees. Accordingly, in the present embodiment, it is preferable to increase inclination γ of the side face to be greater than 90 degrees. In this case, growth inhibiting film 5 can be efficiently provided on side face 111 of recessed region 11. Inclination γ of side face 111 can be adjusted by controlling etching conditions or the like when etching the recessed region.

Thickness of Growth Inhibiting Film

It is not preferable that the growth inhibiting film has such thickness that the groove created by recessing is completely filled up with the growth inhibiting film, because the occurrence of cracks cannot be prevented in such a state. Accordingly, a state where the groove is not completely filled up with the growth inhibiting film is preferable. More preferably, a thickness t1 shown in FIG. 10A is smaller than or equal to half of a recess depth f (f shown in FIGS. 1A and 1B), and a thickness t2 is preferably smaller than or equal to half of an opening width g of the recessed region (g shown in FIGS. 1A and 1B). When growth inhibiting film 5 is thicker than these thicknesses, the recessed region cannot be ensured, so that the effect of preventing the occurrence of cracks will be lost. In addition, nonuniformity in composition in the cladding layer will be increased. A preferable relationship between thicknesses t1 and t2 is t1≧t2. In this case, failures such as stripping of the growth inhibiting film decrease.

Growth Inhibiting Area

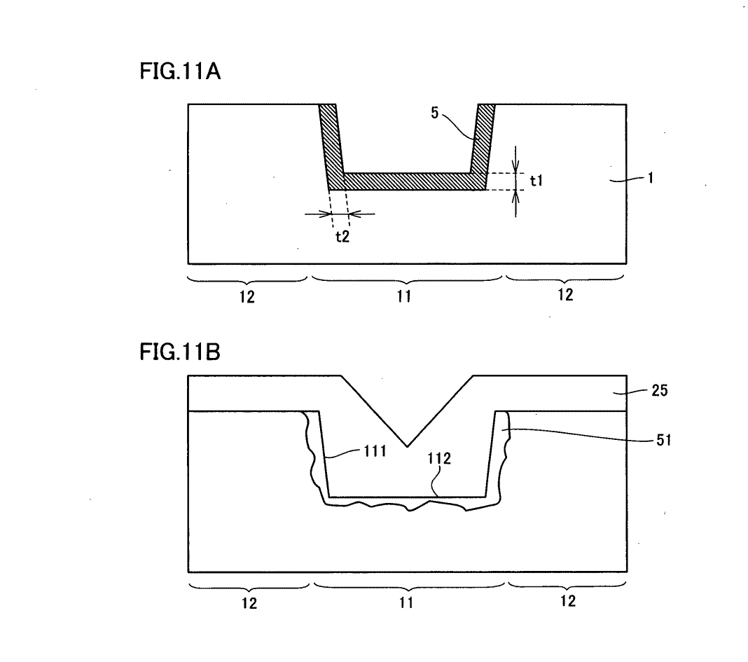

When the growth inhibiting film is thin (e.g., having a thickness of approximately 10 to 50 nm), the nitride semiconductor thin film, when grown at a growth temperature of approximately 700 to 1000° C., is mixed with a nitride semiconductor serving as the substrate, producing a mixed crystal. This phenomenon will be explained with reference to FIGS. 11A and 11B. First, growth inhibiting film 5 made of AlN (aluminum nitride) is provided in recessed region 11 of nitride semiconductor substrate 1 (FIG. 11A) by the method as described with reference to FIGS. 9A-9F and 10A-10C. At this stage, thicknesses t1 and t2 of growth inhibiting film 5 shown in FIG. 11A are both 10 nm. Nitride semiconductor substrate 1 with growth inhibiting film 5 provided thereon is then loaded into a growth oven of an MOCVD apparatus, where an n-type GaN thin film 25 is grown on the surface at a growth temperature of 1000° C. The state thereafter is shown in FIG. 11B. When the temperature is raised to 1000° C. for growing n-type GaN thin film 25, MN contained in growth inhibiting film 5 and GaN contained in nitride semiconductor substrate 1 are melted to turn into a mixed crystal of AlGaN. In this manner, it has been found out that growth inhibiting film 5 is not necessarily maintained as it is while the nitride semiconductor thin film is grown, and an area having a composition different from that of another portion of nitride semiconductor substrate 1 (hereinafter referred to as a growth inhibiting area 51) at side face 111 and bottom face 112 of recessed region 11 in nitride semiconductor substrate 1, such as the above-mentioned area where the mixed crystal of AlGaN is produced, exerts the same effects as those of the growth inhibiting film.

When the growth inhibiting film is thick, a portion thereof may be melted with the nitride semiconductor substrate to produce the growth inhibiting area, on which the remaining portion of the growth inhibiting film is present, thus exhibiting a double-layered-like structure. The effects can also be achieved in such case. When embodying growth inhibiting film 5 as shown in FIG. 10B or 10C, similar effects can also be achieved.

When the growth inhibiting area is produced, there is no step difference between the growth inhibiting area and the surface of the nitride semiconductor substrate. In contrast, the growth inhibiting film creates a step difference between the nitride semiconductor substrate and the growth inhibiting film. The growth inhibiting area creating no such step difference can bring about the growth more smoothly, which is more preferable in terms of surface morphology.

In the case of replacing the above-described growth inhibiting film made of MN with a growth inhibiting film made of AlON (an aluminum oxynitride film), for example, the growth inhibiting film is melted with the nitride semiconductor substrate made of GaN to produce a growth inhibiting area of AlGaON.

The growth inhibiting film may be melted not only with the nitride semiconductor substrate but also with the nitride semiconductor thin film to be provided thereon. In this case, similar effects to those described above can also be achieved, because melting assists achieving the effect of inhibiting the growth of the nitride semiconductor thin film.

Types of Growth Inhibiting Film

The growth inhibiting film is preferably embodied by an aluminum nitride film, an aluminum oxynitride film or an aluminum gallium nitride film. These materials are highly effective in achieving all of the effects of preventing the occurrence of cracks, improving the surface morphology and minimizing nonuniformity in Al composition in the cladding layer. Since these materials can assume the same crystal structure as that of the nitride semiconductor thin film, the crystal structure is continuous from the growth inhibiting film to another region without the growth inhibiting film, which is more preferable. For these reasons, it is considered that the above-described preferable effects can be achieved.

Less preferable materials are silicon oxide, silicon nitride, silicon oxynitride, aluminum oxide, titanium (Ti) oxide, zirconium (Zr) oxide, yttrium (Y) oxide, silicon (Si) oxide, niobium (Nb) oxide, hafnium (Hf) oxide, tantalum (Ta) oxide, and oxynitrides or nitrides of these materials. Still less preferable materials are high-melting metals such as molybdenum, tungsten and tantalum.

The growth inhibiting area is preferably embodied by an aluminum nitride film, an aluminum oxynitride film, an aluminum gallium nitride film or an aluminum gallium oxynitride film.

Inner Shape of Recessed Region of Growth Inhibiting Film

The growth inhibiting film embodied by any of the three patterns shown in FIGS. 10A to 10C exerts the effect of minimizing nonuniformity in Al composition in the nitride semiconductor layer.

The second embodiment can achieve effects similar to or more advantageous than those of the first embodiment. It should be noted that the first embodiment can achieve the effects of the present invention without providing the growth inhibiting film as in the present embodiment.

### Third Embodiment

The present embodiment is basically the same as the first embodiment except that the substrate is embodied by a GaN substrate having A plane {11-20} with a recessed region created in the stripe shape by vapor phase etching at a width of 5 μm, a depth of 3 μm and a cycle of 400 μm in the <1-100> direction. No growth inhibiting film is provided. The present embodiment can also achieve effects similar to those of the first embodiment.

### Fourth Embodiment

The present embodiment is basically the same as the second embodiment except that the substrate is embodied by a GaN substrate having A plane {11-20} with a recessed region created in the stripe shape by vapor phase etching at a width of 5 μm, a depth of 3 μm and a cycle of 400 μm in the <0001> direction. A growth inhibiting film made of SiO₂ is employed. The growth inhibiting film has the profile shown in FIG. 10A. Thickness t1 and thickness t2 shown in FIG. 10A are set at 0.3 μm and 0.1 μm, respectively. The present embodiment can also achieve effects similar to those of the first embodiment.

### Fifth Embodiment

The present embodiment is basically the same as the second embodiment except that the substrate is embodied by a GaN substrate having a semipolar plane {11-22} with a recessed region created in the stripe shape by vapor phase etching at a width of 5 μm, a depth of 3 μm and a cycle of 400 μm in the <−1-123> direction. A growth inhibiting film made of Al₂O₃ is employed. The growth inhibiting film has the profile shown in FIG. 10A. Thickness t1 and thickness t2 shown in FIG. 10A are set at 0.3 μm and 0.1 μm, respectively. The present embodiment can also achieve the effects of preventing the occurrence of cracks, improving the surface morphology and minimizing nonuniformity in composition in the AlGaN nitride semiconductor thin film.

### INDUSTRIAL APPLICABILITY

A nitride semiconductor light-emitting device obtained by the present invention is used for a light source of a semiconductor optical apparatus, for example.

Although the present invention has been described and illustrated in detail, it is clearly understood that the same is by way of illustration and example only and is not to be taken by way of limitation, the scope of the present invention being interpreted by the terms of the appended claims.

What is clamed is:

1. A method for fabricating a nitride semiconductor light-emitting device, including the steps of:
creating a recessed region in a nitride semiconductor substrate having a nonpolar plane or a semipolar plane; and
providing a nitride semiconductor thin film including an n-type nitride semiconductor thin film, an active layer and a p-type nitride semiconductor thin film on the nitride semiconductor substrate, wherein
said p-type nitride semiconductor thin film is grown at a growth temperature higher than or equal to 700° C. and lower than 900° C.

2. The method for fabricating a nitride semiconductor light-emitting device according to claim 1, wherein said p-type nitride semiconductor thin film contains Al.

3. The method for fabricating a nitride semiconductor light-emitting device according to claim 1, wherein said n-type nitride semiconductor thin film is grown at a growth temperature higher than or equal to 900° C.

4. The method for fabricating a nitride semiconductor light-emitting device according to claim 1, wherein said active layer includes a well layer made of InₓGa₁₋ₓN (where x is more than or equal to 0.15).

5. The method for fabricating a nitride semiconductor light-emitting device according to claim 4, wherein said well layer is grown at a growth temperature higher than or equal to 600° C. and lower than or equal to 830° C.

6. The method for fabricating a nitride semiconductor light-emitting device according to claim 1, wherein said nitride semiconductor substrate having a nonpolar plane or a semipolar plane is a nitride semiconductor substrate having an M plane which is a nonpolar plane.

7. The method for fabricating a nitride semiconductor light-emitting device according to claim 6, wherein said recessed region is arranged in a stripe shape in a main surface of said nitride semiconductor substrate, and the stripe shape extends in parallel to a c-axis <0001> direction.

8. The method for fabricating a nitride semiconductor light-emitting device according to claim 7, wherein at said nitride semiconductor substrate having an M plane, an off-angle in a direction parallel to the c-axis <0001> direction ranges from 0.5 to 10 degrees.

9. The method for fabricating a nitride semiconductor light-emitting device according to claim 8, wherein at said nitride semiconductor substrate having an M plane, an off-angle in a direction perpendicular to the c-axis is smaller than the off-angle in the direction parallel to the c-axis.

10. The method for fabricating a nitride semiconductor light-emitting device according to claim 1, wherein a growth inhibiting film or a growth inhibiting area is provided at a surface of said nitride semiconductor substrate in said recessed region.
